(19) United States
(12) Patent Application Publication
(10) Pub. No.: US 2025/0006762 A1
(43) Pub. Date: Jan. 2, 2025

(54) Pixel Structures in Image Sensors

(71) Applicant: Taiwan Semiconductor Manufacturing Company, Ltd, Hsinchu (TW)

(72) Inventors: Chun-Chieh CHUANG, Tainan City (TW); Hsin-Hung CHEN, Tainan City (TW); Wen-I HSU, Tainan City (TW); Peng-Chieh CHIN, Tainan City (TW); Feng-Chi HUNG, Chu-Bei City (TW); Ming-En CHEN, Tainan City (TW); Jen-Cheng LIU, Hsin-Chu City (TW); Dun-Nian YAUNG, Tainan City (TW)

(73) Assignee: Taiwan Semiconductor Manufacturing Company, Ltd., Hsinchu (TW)

(21) Appl. No.: 18/411,506

(22) Filed: Jan. 12, 2024

Related U.S. Application Data
(60) Provisional application No. 63/523,391, filed on Jun. 27, 2023.

(51) Int. Cl. H01L 27/146

(52) U.S. Cl. CPC H01L 27/1463; H01L 27/14612; H01L 27/14632; H01L 27/14636; H01L 27/1464; H01L 27/14687

(57) ABSTRACT

An optical device and a method of fabricating the same are disclosed. The optical device includes a first die layer and a second die layer. The first die layer includes a first substrate having a first surface and a second surface opposite to the first surface, first and second pixel structures, an inter-pixel isolation structure disposed in the first substrate and surrounding the first and second pixel structures, and a floating diffusion region disposed in the first substrate and between the first and second pixel structures. The second die layer includes a second substrate having a third surface and a fourth surface opposite to the third surface and a pixel transistor group disposed on the third surface of the second substrate and electrically connected to the first and second pixel structures.

### CROSS-REFERENCE TO RELATED APPLICATION

This application claims the benefit of U.S. Provisional Patent Application No. 63/523,391, titled “Layout for Multi-Layered Pixel Device,” filed on Jun. 27, 2023, the disclosure of which is incorporated by reference herein in its entirety.

### p BACKGROUND

Image sensors are used to sense incoming visible or non-visible radiation, such as visible light and infrared light. Complementary metal-oxide-semiconductor (CMOS) image sensors (CIS) and charge-coupled device (CCD) sensors are used in various applications, such as digital still cameras, mobile phones, tablets, and goggles. These image sensors utilize an array of pixel structures that absorb (e.g., sense) an incoming radiation and convert it into electrical signals. An example of an image sensor is a back-side illuminated (BSI) image sensor, which detects radiation from a “back-side” of a substrate of the BSI image sensor.

### BRIEF DESCRIPTION OF THE DRAWINGS

Aspects of this disclosure are best understood from the following detailed description when read with the accompanying figures.

FIGS. 1A-1G illustrate different cross-sectional view of a BSI image sensor, in accordance with some embodiments.

FIG. 2 is a flow diagram of a method for fabricating a BSI image sensor, in accordance with some embodiments.

FIGS. 3-8 illustrate cross-sectional views of a BSI image sensor at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

A BSI image sensor includes an array of pixel structures (also referred to as “pixel units,” “pixel cells,” “pixel regions,” and “pixels”) on a first substrate of a first die layer. The pixel structures are configured to receive (or absorb) an electromagnetic radiation (e.g., infra-red radiation) projected toward a back-side of the first substrate and convert photons from the received radiation to electrical signals through pixel transistor groups on a second substrate of a second die layer bonded to the first die layer. Each pixel transistor group can include a source follower transistor, a row selector transistor, and a reset transistor. The electrical signals are subsequently distributed to logic circuits on a third substrate of a third die layer bonded to the second die layer.

In the BSI image sensor, an interconnect layer is disposed on a front-side of the first substrate to electrically connect the pixel structures to the pixel transistor groups. And, color filters and micro-lenses are disposed on the back-side of the first substrate to collect light with minimal or no obstructions from the elements of the interconnect layer and/or the pixel structures. As a result, BSI image sensors have improved performance under low light conditions and higher quantum efficiency (QE) (e.g., photon to electron conversion percentage) than front-side illuminated image sensors.

The present disclosure provides example structures of a BSI image sensor for improving sensor performance (e.g., increasing sensitivity to radiation, increasing full well capacity, reducing capacitance, and/or reducing cross-talk between adjacent pixel structures) and reducing manufacturing costs of the BSI image sensor. In some embodiments, the BSI image sensor can include dual radiation-sensing device (RSD)-based pixel structures, each of which can include first and second RSDs and does not include more than two RSDs. Each of the first and second RSDs can have a rectangular-shaped radiation-sensing surface area. The rectangular-shaped radiation-sensing surface areas in each of the dual RSD-based pixel structures can provide a larger radiation-sensing surface area than a similar sized quadratic RSD-based pixel structure having four RSDs with square-shaped radiation-sensing surface areas. As a result, the dual RSD-based pixel structure can improve sensor performance (e.g., increased sensitivity to radiation and/or increased full well capacity) than quadratic RSD-based pixel structure.

In some embodiments, the BSI image sensor can further include inter-pixel isolation structures (also referred to as “inter-pixel deep trench isolation (DTI) structures”) surrounding each pixel structure to reduce electrical and optical cross-talk between adjacent pixel structures. Also, intra-pixel isolation structures can be disposed between the first and second RSDs in each pixel structure to reduce electrical and optical cross-talk between the first and second RSDs of each pixel structure.

In some embodiments, each pair of adjacent pixel structures of the BSI image sensor can share a floating diffusion region and a pixel transistor group to reduce the manufacturing cost of the BSI image sensor compared to other BSI image sensors having an individual floating diffusion region and an individual pixel transistor group for each pixel structure. In addition, each floating diffusion region and each pair of adjacent pixel structures can be electrically coupled to a corresponding pixel transistor group through a single metal line layer in the interconnect layer of the first die layer. With the use of the single metal line layer, the manufacturing cost of the BSI image sensor can be further reduced compared to other BSI image sensors using multiple metal line layers for electrically coupling floating diffusion regions and pixel structures to corresponding pixel transistor groups.

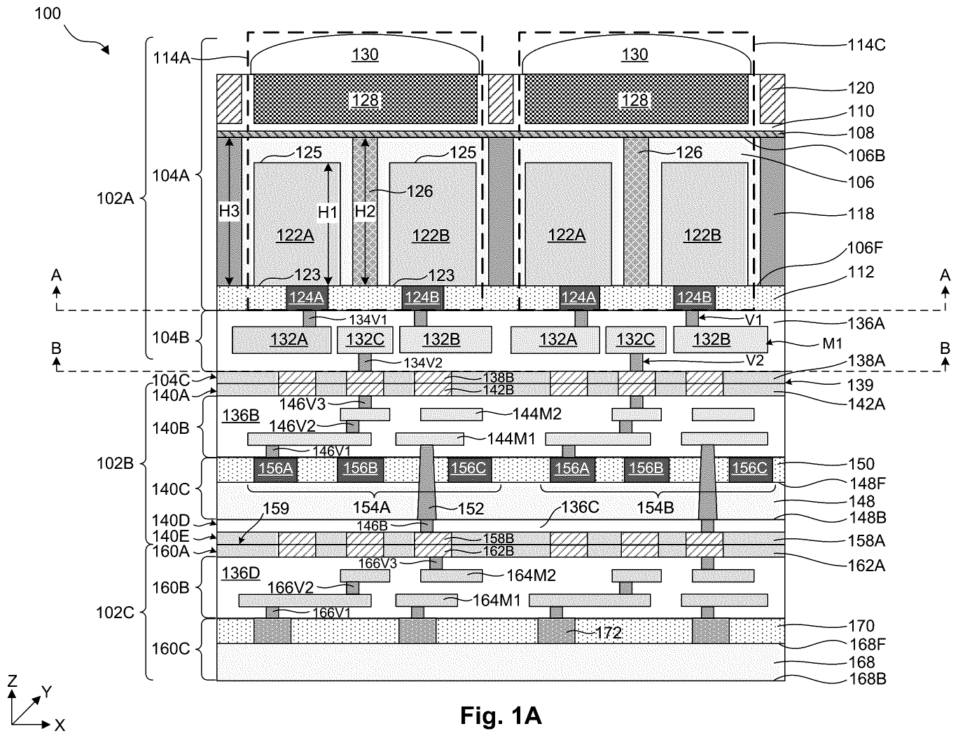

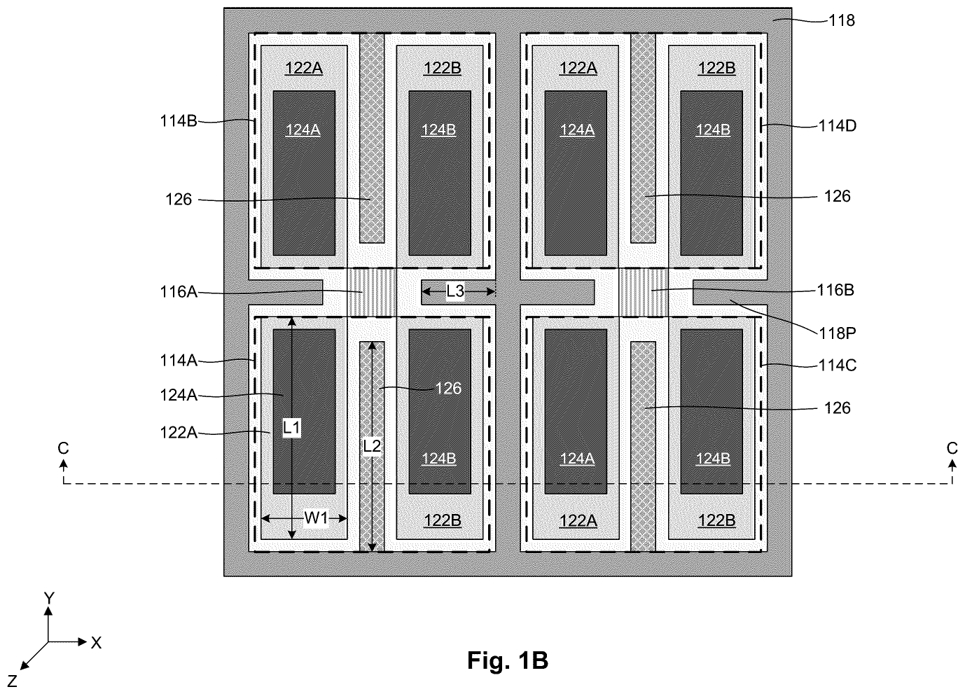

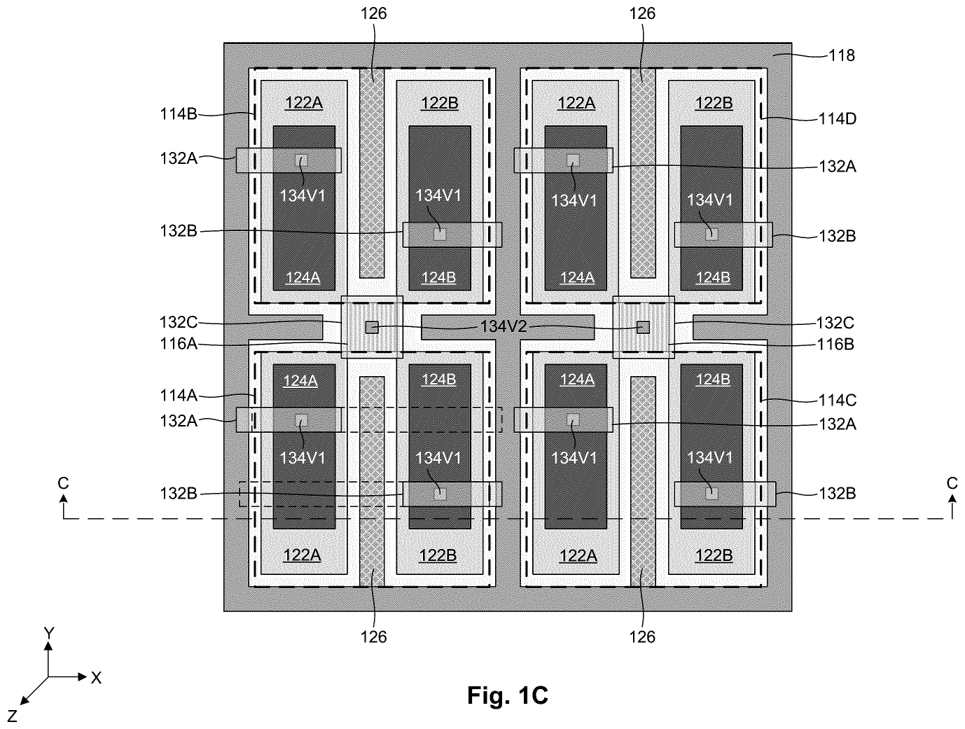

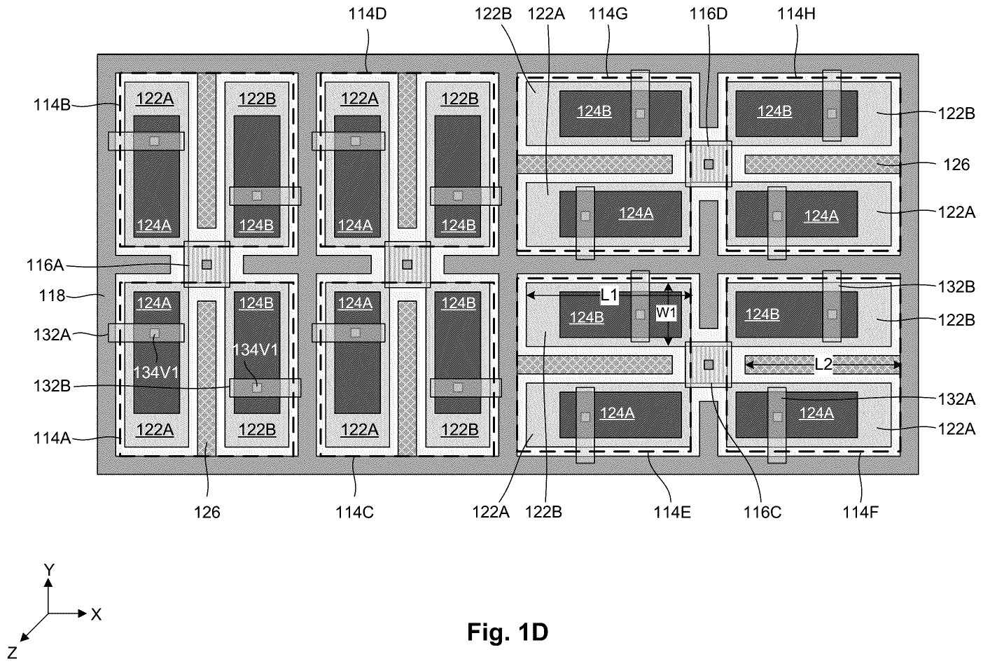

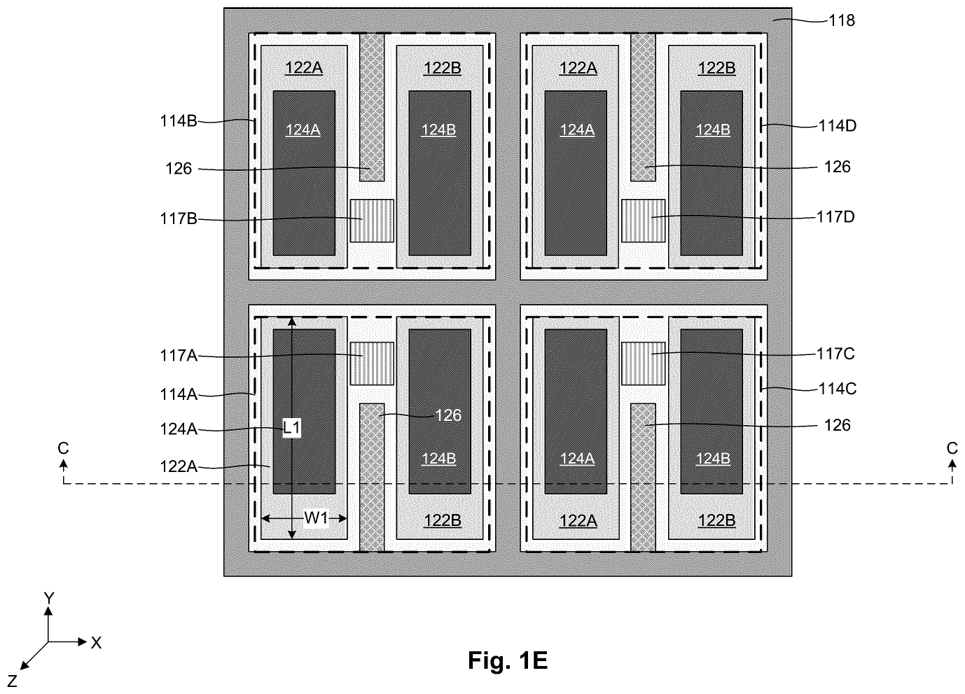

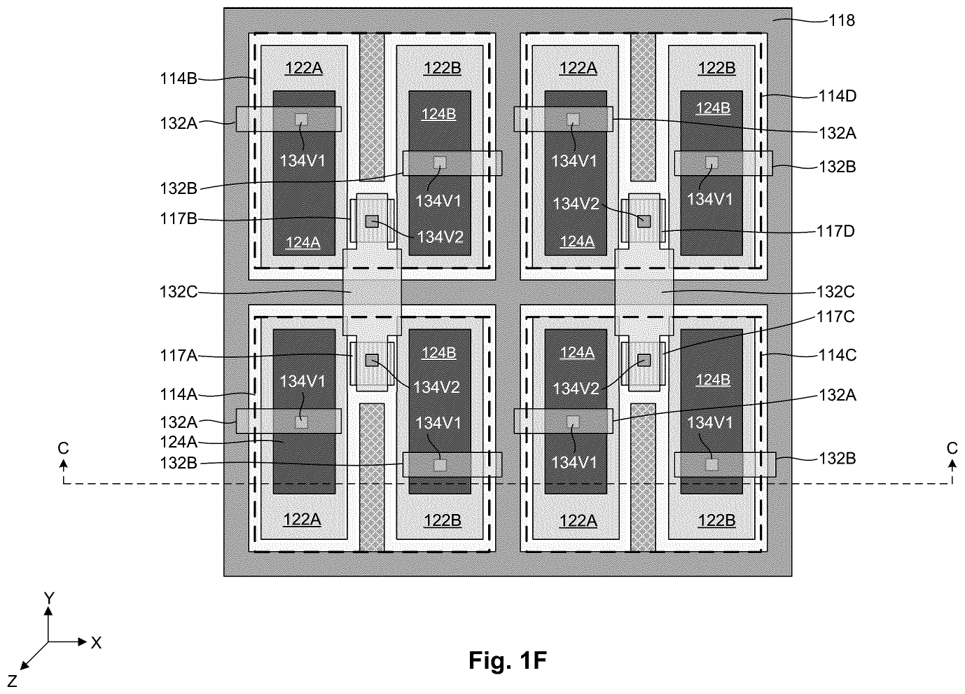

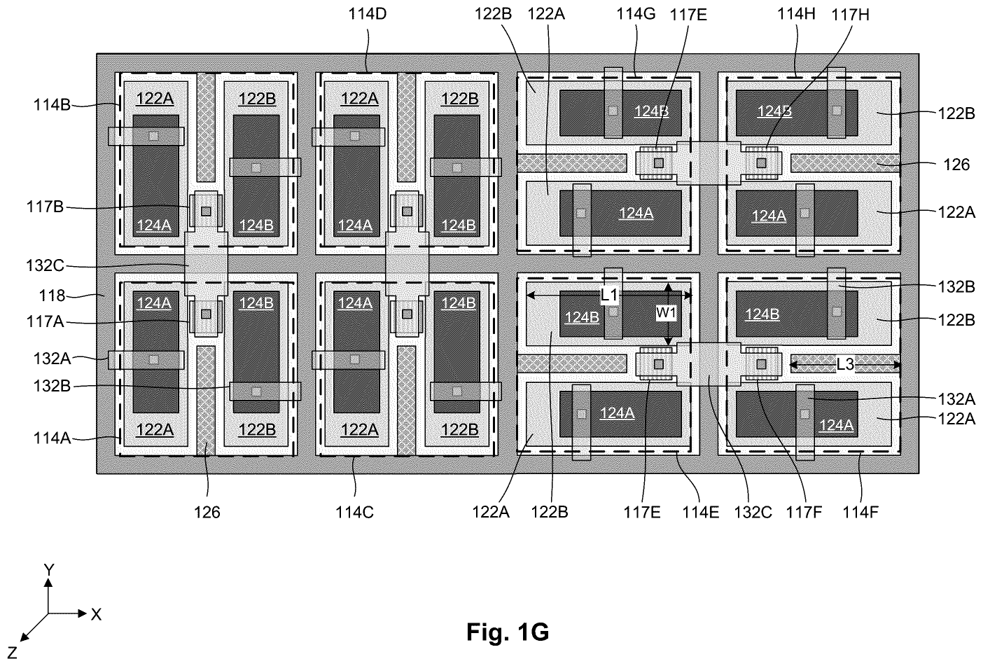

FIG. 1A illustrates a vertical cross-sectional view of a BSI image sensor 100 (also referred to as an “optical device 100”) along an XZ-plane, according to some embodiments. FIGS. 1B and 1E illustrate different horizontal cross-sectional views of BSI image sensor 100 along XY-planes and along line A-A of FIG. 1A, according to some embodiments. FIGS. 1C, 1D, IF, and 1G illustrate different horizontal cross-sectional views of BSI image sensor 100 along XY-planes and along line B-B of FIG. 1A, according to some embodiments. In some embodiments, FIG. 1A can be a vertical cross-sectional view of BSI image sensor 100 along line C-C of FIGS. 1B, 1C, 1E, and 1F. FIGS. 1B-1G illustrate horizontal cross-sectional views of BSI image sensor 100 with additional structures that are not visible in FIG. 1A or that are not shown in FIG. 1A for simplicity. The discussion of elements in FIGS. 1A-1G with the same annotations applies to each other, unless mentioned otherwise.

Referring to FIG. 1A, in some embodiments, BSI image sensor 100 can include (i) a first die layer 102A, (ii) a second die layer 102B bonded to first die layer 102A, and (iii) a third die layer 102C bonded to second die layer 102B. In some embodiments, first die layer 102A can include (i) a device layer 104A, (ii) an interconnect layer 104B, and (iii) a bonding layer 104C.

Referring to FIGS. 1A-1C, in some embodiments, device layer 104A can include (i) a substrate 106 having a back-side surface 106B and a front-side surface 106F, (ii) an anti-reflective coating layer 108 disposed on back-side surface 106B of substrate 106, (iii) a dielectric layer 110 disposed on anti-reflective coating layer 108, (iv) an interlayer dielectric (ILD) layer 112 disposed on front-side surface 106F of substrate 106, (v) pixel structures 114A-114D, (vi) floating diffusion regions 116A and 116B, (vii) an inter-pixel isolation structure 118, and (viii) metal grid structures 120. ILD layer 112 is not shown in FIGS. 1B and 1C for simplicity. Pixel structures 114B and 114D and floating diffusion regions 116A and 116B are not visible in FIG. 1A. Though four pixel structures 114A-114D are shown in FIGS. 1A-1C, BSI image sensor 100 can have any number of pixel structures.

In some embodiments, substrate 106 can include a semiconductor material, such as silicon, germanium (Ge), silicon germanium (SiGe), a silicon-on-insulator (SOI) structure, and a combination thereof. Further, substrate 106 can be doped with p-type dopants (e.g., boron, indium, aluminum, or gallium) or n-type dopants (e.g., phosphorus or arsenic).

In some embodiments, anti-reflective coating layer 108 can be disposed on back-side surface 106B of substrate 106 to prevent incident radiation from being reflected away from pixel structures 114A-114D. In some embodiments, anti-reflective coating layer 108 can include a high-k dielectric material, such as hafnium oxide (HfO₂), tantalum pentoxide (Ta₂O₅), zirconium dioxide (ZrO₂), aluminum oxide (Al₂O₃), and any other suitable high-k dielectric material. In some embodiments, dielectric layer 110 and ILD layer 112 can include a dielectric material, such as silicon oxide (SiO₂), silicon nitride (Si₃N₄), silicon oxynitride (SiON), or any other suitable dielectric material. In some embodiments, dielectric layer 110 and ILD layer 112 can include the same dielectric material or a dielectric material different from each other.

In some embodiments, each of pixel structures 114A-114D can include (i) RSDs 122A and 122B (also referred to as “radiation sensing regions 122A and 122B”), (ii) transfer gate structures 124A and 124B, (iii) an intra-pixel isolation structure 126, (iv) a color filter 128, and (v) a micro-lens 130. RSDs 122A and 122B can be disposed in substrate 106. In some embodiments, RSDs 122A and 122B can include an epitaxial semiconductor layer having silicon, germanium, silicon germanium, or other semiconductor materials in the III-V group, such as gallium arsenide, gallium phosphide, indium phosphide, and gallium nitride depending on the radiation wavelength of interest. For example, an epitaxial silicon layer can be used for visible light applications (e.g., between about 380 nm to about 740 nm) and an epitaxial germanium layer can be used for infrared applications (e.g., for wavelengths between about 940nm and about 1550 nm). An epitaxial silicon germanium layer can be used for wavelengths between visible radiation and infrared radiation. In some embodiments, each of RSDs 122A and 122B can include a photodiode. Top surfaces 123 of RSDs 122A and 122B can be substantially coplanar with front-side surface 106F of substrate 106. Radiation-sensing surfaces 125 of RSDs 122A and 122B face back-side surface 106B of substrate 106 and detect the radiation entering through back-side surface 106B of substrate 106. The photons of the detected radiation can generate electron-hole pairs, which can be subsequently converted into electrical signals, as described in detail below.

Each of pixel structures 114A-114D includes two RSDs 122A and 122B and does not include more than two RSDs. As a result, pixel structures 114A-114D can be referred to as dual RSD-based pixel structures 114A-114D. Each of top surfaces 123 and radiation-sensing surfaces 125 of RSDs 122A and 122B can have a rectangular-shaped surface area. In some embodiments, the rectangular-shaped surface area can have a width W1 and a length L1 greater than width W1. In some embodiments, width W1 can be about 0.15 μm to about 2 μm and length L1 can be about 0.4 μm to about 4 μm. In some embodiments, a ratio between length L1 and width W1 (L1:W1) can be about 1.5 to about 3. Within these dimension ranges of length L1 and width W1, radiation-sensing surfaces 125 can provide surface area for adequate detection of radiation entering through back-side surface 106B of substrate 106. In addition, within these dimension ranges of length L1 and width W1, radiation-sensing surfaces 125 can provide larger detection areas and higher sensitivity to radiation detection along with greater full well capacity than other BSI image sensors with quadratic RSD-based pixel structures.

In some embodiments, transfer gate structures 124A can be disposed on top surfaces 123 of RSDs 122A and in ILD layer 112. And, transfer gate structures 124B can be disposed on top surfaces 123 of RSDs 122B and in ILD layer 112. Each of transfer gate structures 124A and 124B can include a gate dielectric layer (not shown) disposed on top surfaces 123 and a gate metal layer (not shown) disposed on the gate dielectric layer. In some embodiments, the gate dielectric layer can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), zirconium aluminum oxide (ZrAIO), zirconium silicate (ZrSiO₂), lanthanum oxide (La₂O₃), aluminum oxide (Al₂O₃) zinc oxide (ZnO), hafnium zinc oxide (HfZnO), and yttrium oxide (Y₂O₃). In some embodiments, the gate metal layer can include a conductive material, such as tungsten (W), titanium (Ti), silver (Ag), ruthenium (Ru), molybdenum (Mo), copper (Cu), cobalt (Co), aluminum (Al), iridium (Ir), nickel (Ni), metal alloys, and a combination thereof.

Transfer gate structures 124A and 124B can control the transfer of electrons from RSDs 122A and 122B, respectively, to other elements of BSI image sensor 100, as described in detail below. In some embodiments, RSDs 122A and 122B may not have any other transistors disposed directly on top surfaces 123 besides transfer gate structures 124A and 124B, respectively. In some embodiments, first die layer 102A may be free of other logic devices (e.g., logic transistors) besides first and second transfer gate transistors 124A and 124B. In some embodiments, first die layer 102A may not have peripheral circuits for signal processing of BSI image sensor 100. The elements for signal processing of BSI image sensor 100 can be in second and/or third die layers 102B and 102C, as described below. Gate spacers (not shown) can be disposed on sidewalls of transfer gate structures and can include an insulating material, such as SiO₂, SiN, SiON, silicon oxycarbide (SiOC), silicon carbon nitride (SiCN), silicon oxycarbon nitride (SiOCN), and SiGeOx.

In some embodiments, intra-pixel isolation structure 126 can be disposed in substrate 106 and between RSDs 122A and 122B. Intra-pixel isolation structure 126 can extend horizontally to a length L2 along the elongated sides of RSDs 122A and 122B, as shown in FIGS. 1B and 1C. In some embodiments, intra-pixel isolation structure 126 can extend vertically along a Z-axis from front-side surface 106F to back-side surface 106B of substrate 106, as shown in FIG. 1A. In some embodiments, a top surface of intra-pixel isolation structure 126 can be substantially coplanar with front-side surface 106F of substrate 106 and a bottom surface of intra-pixel isolation structure 126 can be substantially coplanar with back-side surface 106B of substrate 106. In some embodiments, top surface of intra-pixel isolation structure 126 can be in contact with ILD layer 112 and back surface of intra-pixel isolation structure 126 can be in contact with anti-reflective coating layer 108. In some embodiments, intra-pixel isolation structures 126 can be extended portions of inter-pixel isolation structure 118. In some embodiments, intra-pixel isolation structures 126 may not be in contact with inter-pixel isolation structure 118 (as shown in FIGS. 1B and 1C), instead can be separated (not shown) from inter-pixel isolation structure 118 by a portion of substrate 106.

In some embodiments, intra-pixel isolation structure 126 can have a height H2 greater than height H1 of each RSDs 122A and 122B. In some embodiments, length L2 of intra-pixel isolation structure 126 can be less than or equal to length L1 of each RSDs 122A and 122B. In some embodiments, a ratio between lengths L1 and L2 (L1:L2) can be about 1:0.5 to about 1:1. Within this range of relative dimensions, intra-pixel isolation structure 126 can adequately prevent or minimize electrical and optical cross-talk between RSDs 122A and 122B, thus improving the quantum efficiency of pixel structures 114A-114D. In some embodiments, intra-pixel isolation structure 126 can include SiO₂, SIN, SiON, HfO₂, Al₂O₃, or any other suitable high-k dielectric material.

In some embodiments, color filter 128 can be disposed in dielectric layer 110 and top surface of color filter 128 can be substantially coplanar with top surface of dielectric layer 110. In some embodiments, each color filter 128 can overlap the entire radiation-sensing surfaces 125 of the underlying pair of RSDs 122A and 122B in each of pixel structures 114A-114D. In some embodiments, color filter 128 can include a polymeric material. In some embodiments, micro-lens 130 can be disposed on color filter 128 and each micro-lens can overlap the entire radiation-sensing surfaces 125 of the underlying pair of RSDs 122A and 122B in each of pixel structures 114A-114D.

Floating diffusion regions 116A and 116B (also referred to as “floating diffusion nodes 116A and 116B”) can be disposed in substrate 106 and can be non-overlapping with RSDs 122A and 122B, as shown in FIGS. 1B and 1C. In some embodiments, floating diffusion regions 116A and 116B can be non-overlapping with intra-pixel isolation structures 126 and inter-pixel isolation structures 118 in XZ-and YZ-planes. In some embodiments, floating diffusion regions 116A and 116B can include doped regions disposed in substrate 106. In some embodiments, the doped regions can include n-type dopants when substrate 106 includes p-type dopants.

Floating diffusion region 116A can be disposed in a substrate region between pixel structures 114A and 114B and floating diffusion region 116B can be disposed in a substrate region between pixel structures 114C and 114D, as shown in FIGS. 1B and 1C. With such placement of floating diffusion regions 116A and 116B, the function of a floating diffusion region can be shared by two pixel structures of BSI image sensor 100, instead of having a floating diffusion region for each pixel structure as in other BSI image sensors. In other words, floating diffusion region 116A can store charges (e.g., electrons) transferred by transfer gate structures 124A and 124B from RSDs 122A and 122B, respectively, of pixel structures 114A and 114B. And, floating diffusion region 116B can store charges (e.g., electrons) transferred by transfer gate structures 124A and 124B from RSDs 122A and 122B, respectively, of pixel structures 114C and 114D. Thus, the total number of floating diffusion regions can be equal to half the number of pixel structures in BSI image sensor 100. By reducing the number of floating diffusion regions in BSI image sensor 100, floating diffusion capacitance in BSI image sensor 100 can be reduced, and consequently, conversion gain of BSI image sensor 100 can be increased.

In some embodiments, inter-pixel isolation structure 118 can be disposed in substrate 106 and can surround each pair of RSDs 122A and 122B. In some embodiments, portions of inter-pixel isolation structure 118 can extend laterally between pixel structures 114A and 114B and between pixel structures 114C and 114D, as shown in FIGS. 1B and 1C. In some embodiments, the extended portions can have a length L3, which can be less than or equal to width W1 of each RSDs 122A and 122B. In some embodiments, a ratio between lengths W1 and L3 (W1:L3) can be about 1:0.5 to about 1:1. In some embodiments, a cross-section of inter-pixel isolation structure 118 along an XY-plane includes a rectangular-shaped enclosure or ring around pixel structures 114A and 114B and around pixel structures 114C and 114D, as shown in FIGS. 1B and 1C. In some embodiments, a cross-section of inter-pixel isolation structure 118 along an XY-plane includes a rectangular-shaped enclosure or ring around pixel structures 114A, 114B, 114C, and 114D, as shown in FIGS. 1B and 1C. In some embodiments, a cross-section of inter-pixel isolation structure 118 along an XZ-plane includes a vertical structure separating pixel structures 114A and 114C, as shown in FIG. 1A. The top surface of the vertical structure can be in contact with ILD layer 112 and back surface of the vertical structure can be in contact with anti-reflective coating layer 108, as shown in FIG. 1A.

In some embodiments, inter-pixel isolation structure 118 can extend vertically along a Z-axis from front-side surface 106F to back-side surface 106B of substrate 106, as shown in FIG. 1A. In some embodiments, a top surface of inter-pixel isolation structure 118 can be substantially coplanar with front-side surface 106F of substrate 106 and a bottom surface of inter-pixel isolation structure 118 can be substantially coplanar with back-side surface 106B of substrate 106. In some embodiments, top surface of inter-pixel isolation structure 118 can be in contact with ILD layer 112 and back surface of inter-pixel isolation structure 118 can be in contact with anti-reflective coating layer 108. In some embodiments, inter-pixel isolation structure 118 can have a height H3 greater than height H1 of each RSDs 122A and 122B. Within these ranges of relative dimensions, inter-pixel isolation structure 118 can adequately prevent or minimize electrical and optical cross-talk between pixel structures 114A-114D, thus improving the quantum efficiency of pixel structures 114A-114D. In some embodiments, inter-pixel isolation structure 118 can include SiO₂, SiN, SiON, HfO₂, Al₂O₃, or any other suitable high-k dielectric material.

In some embodiments, metal grid structures 120 can be disposed in dielectric layer 110, between adjacent color filter 128, and on inter-pixel isolation structure 118. In some embodiments, metal grid structures 120 can be separated from inter-pixel isolation structure 118 by a distance of about 100 nm to about 300 nm along a Z-axis for the ease of fabrication. Metal grid structures 120 can minimize or prevent cross-talk between pixel structures 114A-114D.

Referring to FIGS. 1A and 1C, interconnect layer 104B can be disposed on front-side surface 106F of substrate 106 and can electrically connect elements of device layer 104A to elements of second die layer 102B. In some embodiments, interconnect layer 104B can include a single metal line layer M1 and two via layers V1 and V2 disposed in inter-metal dielectric (IMD) layer 136A (not shown in FIG. 1C for simplicity). With the use of the single metal line layer M1, the manufacturing cost of BSI image sensor 100 can be reduced compared other BSI image sensors using multiple metal line layers. In some embodiments, metal line layer M1 can include metal lines 132A-132C, via layer V1 can include conductive vias 134V1, and via layer V2 can include conductive vias 134V2.

In some embodiments, metal lines 132A can be electrically connected to transfer gate structures 124A, metal lines 132B can be electrically connected to transfer gate structures 124B, and metal lines 132C can be electrically connected to floating diffusion regions 116A and 116B through vias 134V1. The layout of metal lines 132A-132C and conductive vias 134V and 134V2 are exemplary and not limiting and other layout variations of metal lines 132A-132C and conductive vias 134V and 134V2 are within the scope of this disclosure. In some embodiments, metal lines 132A and 132B can extend across RSDs 122A and 122B, respectively, as shown with solid lines in FIG. 1C or can extend across both RSDs 122A and 122B and intra-pixel isolation structures 126, as shown with dotted lines in FIG. 1C. In some embodiments, the elongated sides of metal lines 132A and 132B can be perpendicular to the elongated sides of RSDs 122A and 122B.

Referring to FIG. 1A, bonding layer 104C can be disposed on interconnect layer 104B and can include a dielectric layer 138A and metal pads 138B disposed in dielectric layer 138A. Bonding layer 104C can bond first die layer 102A to second die layer 102B and can provide electrical connections between elements of first die layer 102A to elements of second die layer 102B through metal pads 138B. In some embodiments, metal pads 138B can include copper and dielectric layer 138A can include SiO₂, SiN, SiC, SiON, SiCN, or any other suitable dielectric material.

Referring to FIG. 1A, in some embodiments, second die layer 102B can include (i) a front-side bonding layer 140A, (ii) a front-side interconnect layer 140B, (iii) a device layer 140C, (iv) a back-side interconnect layer 140D, and (v) a back-side bonding layer 140E.

Front-side bonding layer 140A can be disposed on front-side interconnect layer 140B and can include a dielectric layer 142A and metal pads 142B disposed in dielectric layer 142A. In some embodiments, metal pads 142B can include copper and dielectric layer 142A can include SiO₂, SiN, SiC, SiON, SiCN, or any other suitable dielectric material. Bonding layer 140A can bond with bonding layer 104C by forming dielectric-to-dielectric bonds between dielectric layers 142A and 138A and metal-to-metal bonds between metal pads 142B and 138B at bonding interface 139, as shown in FIG. 1A. Electrical connections between elements of first die layer 102A to elements of second die layer 102B can be provided through metal pads 138B and 142B.

Front-side interconnect layer 140B can be disposed on device layer 140C and can electrically connect elements of device layer 140C to elements of first die layer 102A. In some embodiments, interconnect layer 140B can include multiple metal line layers having metal lines 144M1 and 144M2 and multiple via layers having conductive vias 146V1-146V3 disposed in IMD layer 136B. The layout and number of metal lines 144M1 and 144M2 and conductive vias 146V1-146V3 are exemplary and not limiting and other layout variations of metal lines 144M1 and 144M2 and conductive vias 146V1-146V3 are within the scope of this disclosure.

In some embodiments, device layer 140C can include (i) a substrate 148 having a back-side surface 148B and a front-side surface 148F, (ii) an ILD layer 150 disposed on front-side surface 148F of substrate 148, (iii) through-silicon vias (TSVs) 152, and (iv) pixel transistor groups 154A and 154B disposed on front-side surface 148F of substrate 148. In some embodiments, substrate 148 can include a semiconductor material similar to or different from substrate 106. In some embodiments, ILD layer 150 can include a dielectric material similar to or different from ILD layer 112. In some embodiments, TSVs 152 can extend vertically through device layer 140A and electrically connect front-side interconnect layer 140B to back-side interconnect layer 140D.

In some embodiments, each of pixel transistor groups 154A and 154B can include pixel transistors, such as (i) a source follower (SF) transistor 156A, (ii) a row selector (RS) transistor 156B, and (iii) a reset (RST) transistor 156C. Pixel transistor group 154A can be electrically connected to transfer gate structures 124A and 124B of pixel structures 114A and 114B and floating diffusion region 116A and can be configured to convert the detected photons from pixel structures 114A and 114B into electrical signals. Similarly, pixel transistor group 154B can be electrically connected to transfer gate structures 124A and 124B of pixel structures 114C and 114D and floating diffusion region 116B and can be configured to convert the detected photons from pixel structures 114C and 114D into electrical signals. With such arrangement of pixel transistor groups 154A and 154B with pixel structures 114A-114B, the function of each pixel transistor group can be shared by two pixel structures of BSI image sensor 100, instead of having a pixel transistor group for each pixel structure as in other BSI image sensors. Thus, the total number of pixel transistor groups can be equal to half the number of pixel structures in BSI image sensor 100. By reducing the number of pixel transistor groups in BSI image sensor 100, the manufacturing cost of BSI image sensor 100 can be reduced compared to other BSI image sensors.

During an example operation of BSI image sensor 100, transfer gate structures 124A and 124B of pixel structure 114A can be selectively turned on to transfer photon-generated electrons from RSDs 122A and 122B of pixel structure 114A into floating diffusion region 116A. The electrons in floating diffusion region 116A can be converted into electrical signals by SF transistor 156A of pixel transistor group 154A, which is electrically connected to floating diffusion region 116A through metal lines 132C, 144M1 and 144M2, conductive vias 134V1, 134V2, and 146V1-146V3, and metal pads 138B and 142B. The RS transistor 156B can select the electrical signals to be read by read-out circuits in third die layer 102C. The RST transistor 156C can be turned on to reset floating diffusion region 116A by clearing the transferred electrons. The reset operation can be followed by selectively turning on transfer gate structures 124A and 124B of pixel structure 114B to transfer electrons from RSDs 122A and 122B of pixel structure 114B into the previously cleared floating diffusion region 116A. The subsequent processing of the transferred electrons can be performed with pixel transistor group 154A, as described above. Similar example operation can be performed with pixel transistor group 154B for converting the photon-generated electrons in pixel structures 114C and 114D into electrical signals.

Referring to FIG. 1A, back-side interconnect layer 140D can be disposed on back-side surface 148B of substrate 148 and can include conductive vias 146B disposed in a dielectric layer 136C. Conductive vias 146B can electrically connect TSVs to elements of third die layer 102C. In some embodiments, back-side bonding layer 140E can be disposed on back-side interconnect layer 140D and can include a dielectric layer 158A and metal pads 158B disposed in dielectric layer 158A. In some embodiments, metal pads 158B can include copper and dielectric layer 158A can include SiO₂, SiN, SiC, SiON, SiCN, or any other suitable dielectric material. Bonding layer 140E can bond second die layer 102B to third die layer 102C and can provide electrical connections between elements of second die layer 102B to elements of third die layer 102C through metal pads 158B.

Referring to FIG. 1A, in some embodiments, third die layer 102C can include (i) a bonding layer 160A, (ii) an interconnect layer 160B, and (iii) a device layer 160C. Bonding layer 160A can be disposed on interconnect layer 160B and can include a dielectric layer 162A and metal pads 162B disposed in dielectric layer 162A. In some embodiments, metal pads 162B can include copper and dielectric layer 162A can include SiO₂, SiN, SiC, SiON, SiCN, or any other suitable dielectric material. Bonding layer 160A can bond with bonding layer 140E by forming dielectric-to-dielectric bonds between dielectric layers 162A and 158A and metal-to-metal bonds between metal pads 162B and 158B at bonding interface 159, as shown in FIG. 1A. Electrical connections between elements of second die layer 102B to elements of third die layer 102C can be provided through metal pads 158B and 162B.

Interconnect layer 160B can be disposed on device layer 160C and can electrically connect elements of device layer 160C to elements of second die layer 102B. In some embodiments, interconnect layer 160B can include multiple metal line layers having metal lines 164M1 and 164M2 and multiple via layers having conductive vias 166V1-166V3 disposed in IMD layer 136D. The layout and number of metal lines 164M1 and 164M2 and conductive vias 166V1-166V3 are exemplary and not limiting and other layout variations of metal lines 164M1 and 164M2 and conductive vias 166V1-166V3 are within the scope of this disclosure.

In some embodiments, device layer 160C can include (i) a substrate 168 having a back-side surface 168B and a front-side surface 168F, (ii) an ILD layer 170 disposed on front-side surface 168F of substrate 168, and (iii) devices 172 disposed on front-side surface 168F of substrate 168. In some embodiments, substrate 168 can include a semiconductor material similar to or different from substrate 106. In some embodiments, ILD layer 170 can include a dielectric material similar to or different from ILD layer 112. In some embodiments, devices 172 can include application-specific integrated circuit (ASIC) devices, such as an analog-to-digital converter (ADC), a counter, a memory storage device, and combinations thereof for processing electrical signals generated by pixel transistor groups 154A and 154B in second die layer 102B.

Referring to FIG. 1D, in some embodiments, BSI image sensor 100 can include pixel structures 114E-114H (not shown in FIG. 1A) in addition to pixel structures 114A-114D. BSI image sensor can further include floating diffusion regions 116C and 116D in addition to floating diffusion regions 116A and 116B. The discussion of pixel structures 114A-114D applies to pixel structures 114E-114H, respectively, and the discussion of floating diffusion regions 116A and 116B applies to floating diffusion regions 116C and 116D, respectively, unless mentioned otherwise. In some embodiments, the directional arrangement of pixel structures 114E-114H can be different from the directional arrangement of pixel structures 114A-114D. For example, the elongated sides of RSDs 122A and 122B and intra-pixel isolation structures 126 of pixel structures 114E-114H can be perpendicular to the elongated sides of RSDs 122A and 122B and intra-pixel isolation structures 126 of pixel structures 114A-114D. In some embodiments, pixel structures 114E and 114F can share the functions of floating diffusion region 116C and a pixel transistor group (not shown) and pixel structures 114G and 114H can share the functions of floating diffusion region 116D and another pixel transistor group (not shown).

Referring to FIGS. 1E and IF, in some embodiments, BSI image sensor 100 can include floating diffusion regions 117A-117D, instead of floating diffusion regions 116A and 116B. Floating diffusion regions 117A-117D can be disposed in substrate 106 and can be non-overlapping with RSDs 122A and 122B. In some embodiments, floating diffusion regions 117A-117D can be non-overlapping with intra-pixel isolation structures 126 and inter-pixel isolation structures 118 in XZ- and YZ-planes. In some embodiments, floating diffusion regions 117A-117D can include doped regions disposed in substrate 106. In some embodiments, the doped regions can include n-type dopants when substrate 106 includes p-type dopants.

Floating diffusion region 117A can be disposed in a substrate region between RSDs 122A and 122B of pixel structure 114A, floating diffusion region 117B can be disposed in a substrate region between RSDs 122A and 122B of pixel structure 114B, floating diffusion region 117C can be disposed in a substrate region between RSDs 122A and 122B of pixel structure 114C, and floating diffusion region 117D can be disposed in a substrate region between RSDs 122A and 122B of pixel structure 114D. With such placement of floating diffusion regions 117A-117D, floating diffusion regions 117A-117D can store electrons transferred from pixel structures 114A-114D, respectively. In some embodiments, floating diffusion regions 117A and 117B can be electrically connected to a common metal line 132C (shown in FIG. 1F), which can be electrically connected to SF transistor 156A of pixel transistor group 154A, as described above. Similarly, floating diffusion regions 117C and 117D can be electrically connected to a common metal line 132C (shown in FIG. 1F), which can be electrically connected to SF transistor 156A of pixel transistor group 154B.

Referring to FIG. 1G, in some embodiments, BSI image sensor 100 can include pixel structures 114E-114H (not shown in FIG. 1A) in addition to pixel structures 114A-114D of FIG. 1F. BSI image sensor 100 can further include floating diffusion regions 117E-117H in addition to floating diffusion regions 117A-117D of FIG. 1F. The discussion of pixel structures 114A-114D applies to pixel structures 114E-114H, respectively, and the discussion of floating diffusion regions 117A-117D applies to floating diffusion regions 117E-117H, respectively, unless mentioned otherwise. In some embodiments, the directional arrangement of pixel structures 114E-114H can be different from the directional arrangement of pixel structures 114A-114D. For example, the elongated sides of RSDs 122A and 122B and intra-pixel isolation structures 126 of pixel structures 114E-114H can be perpendicular to the elongated sides of RSDs 122A and 122B and intra-pixel isolation structures 126 of pixel structures 114A-114D. In some embodiments, floating diffusion regions 117E and 117F can be electrically connected to a common metal line 132C, which can be electrically connected to a SF transistor of a pixel transistor group (not shown). Similarly, floating diffusion regions 117G and 117H can be electrically connected to a common metal line 132C, which can be electrically connected to another SF transistor of another pixel transistor group (not shown).

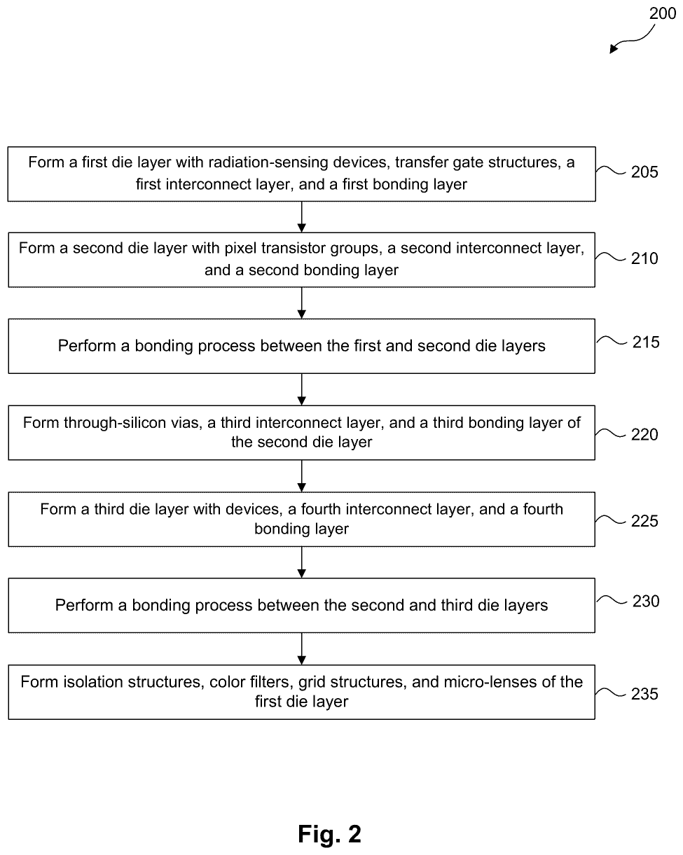

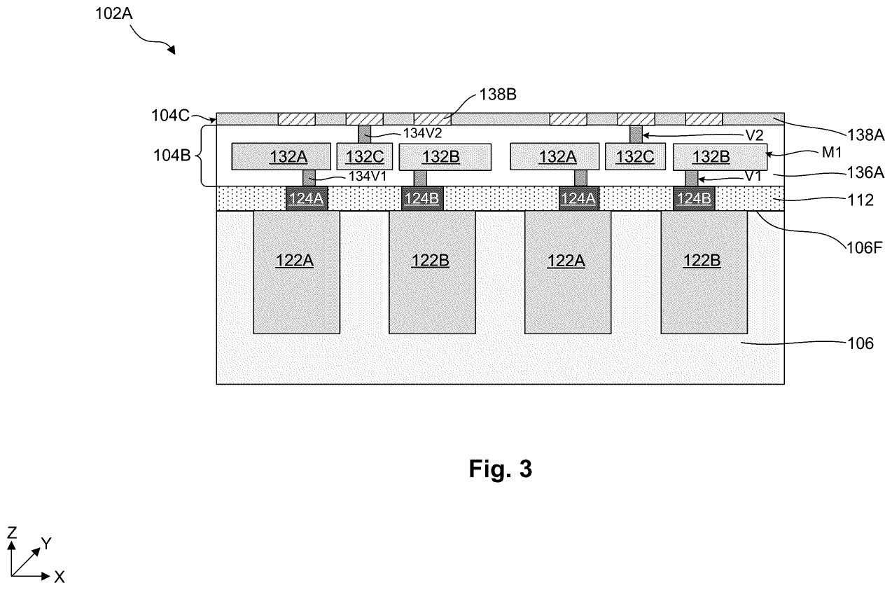

FIG. 2 is a flow diagram of an example method 200 for fabricating BSI image sensor 100, according to some embodiments. For illustrative purposes, the operations illustrated in FIG. 2 will be described with reference to the example fabrication process for fabricating BSI image sensor 100 as illustrated in FIGS. 3-8. FIGS. 3-8 are vertical cross-sectional views of BSI image sensor 100 at various stages of fabrication, according to some embodiments. Operations can be performed in a different order or not performed depending on specific applications. It should be noted that method 200 may not produce a complete BSI image sensor 100.

Accordingly, it is understood that additional processes can be provided before, during, and after method 200, and that some other processes may only be briefly described herein. The discussion of elements in FIGS. 1A-1G and 3-8 with the same annotations applies to each other, unless mentioned otherwise.

Referring to FIG. 2, in operation 205, a first die layer with RSDs, transfer gate structures, a first interconnect layer, and a first bonding layer is formed. For example, as described with reference to FIG. 3, first die layer 102A with RSDs 122A and 122B, transfer gate structures 124A and 124B, interconnect layer 104B, and bonding layer 104C is formed. In some embodiments, the formation of first die layer 102A can include sequential operations of (i) forming RSDs in substrate 106, (ii) forming transfer gate structures 124A and 124B on front-side surface 106F of substrate 106, (iii) depositing ILD layer 112 on front-side surface 106F of substrate 106, (iv) forming conductive vias 134V1 of interconnect layer 104B, (v) forming metal lines 132A-132C of interconnect layer 104B, (vi) forming conductive vias 134V2 of interconnect layer 104B, (vii) depositing dielectric layer 138A of bonding layer 104C on interconnect layer 104B, and (viii) forming metal pads 138B in dielectric layer 138A.

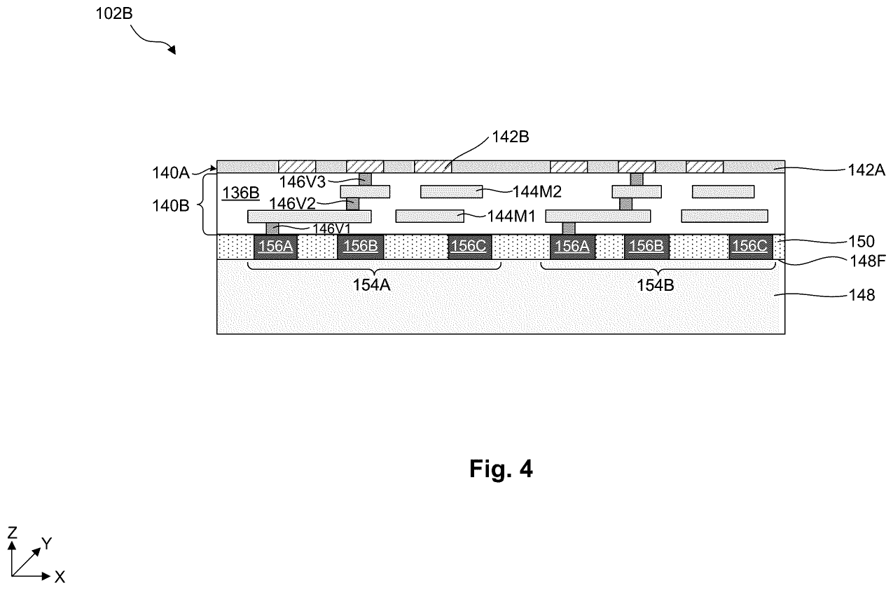

Referring to FIG. 2, in operation 210, a second die layer with pixel transistor groups, a second interconnect layer, and a second bonding layer is formed. For example, as described with reference to FIG. 4, second die layer 102B with pixel transistor groups 154A and 154B, interconnect layer 140B, and bonding layer 140A is formed. In some embodiments, the formation of second die layer 102B can include sequential operations of (i) forming pixel transistor groups 154A and 154B on front-side surface 148F of substrate 148, (ii) depositing ILD layer 150 on front-side surface 148F of substrate 148, (iii) forming conductive vias 146V1 of interconnect layer 140B, (iv) forming metal lines 144M1 of interconnect layer 140B, (v) forming conductive vias 146V2 of interconnect layer 140B, (vi) forming metal lines 144M2 of interconnect layer 140B, (vii) forming conductive vias 146V3 of interconnect layer 140B, (viii) depositing dielectric layer 142A of bonding layer 140A on interconnect layer 140B, and (ix) forming metal pads 142B in dielectric layer 142A.

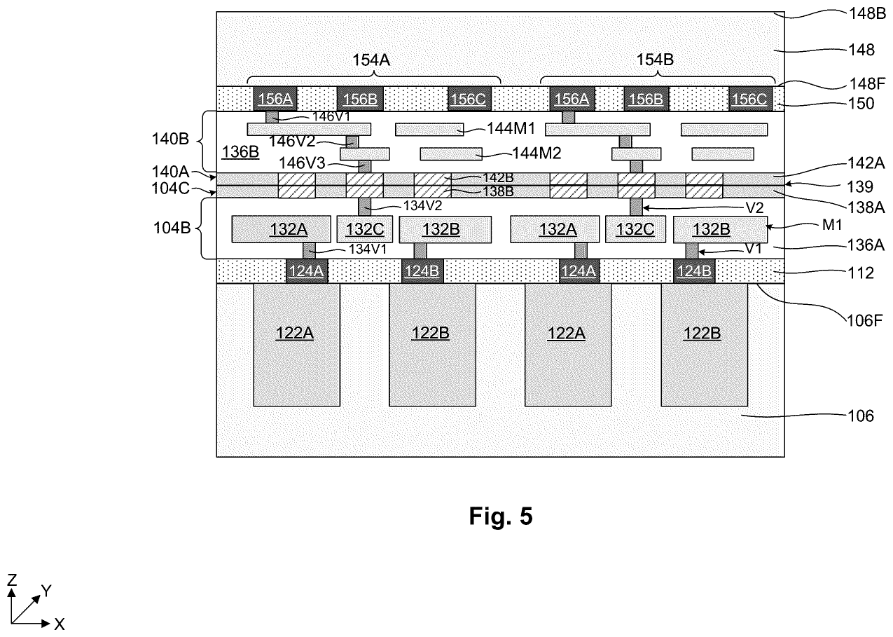

Referring to FIG. 2, in operation 215, a bonding process is performed between the first and second die layers. For example, as described with reference to FIG. 5, a bonding process is performed between first and second die layers 102A and 102B. In some embodiments, performing the bonding process can include sequential operations of (i) performing an activation process with a plasma (e.g., hydrogen plasma) on top surfaces of bonding layers 104C and 140A, (ii) bringing metal pads 138B of bonding layer 104C in contact with corresponding metal pads 142B of bonding layer 140A, and (iii) performing an anneal process at a melting temperature of the material of metal pads 138B and 142B to form the structure of FIG. 5.

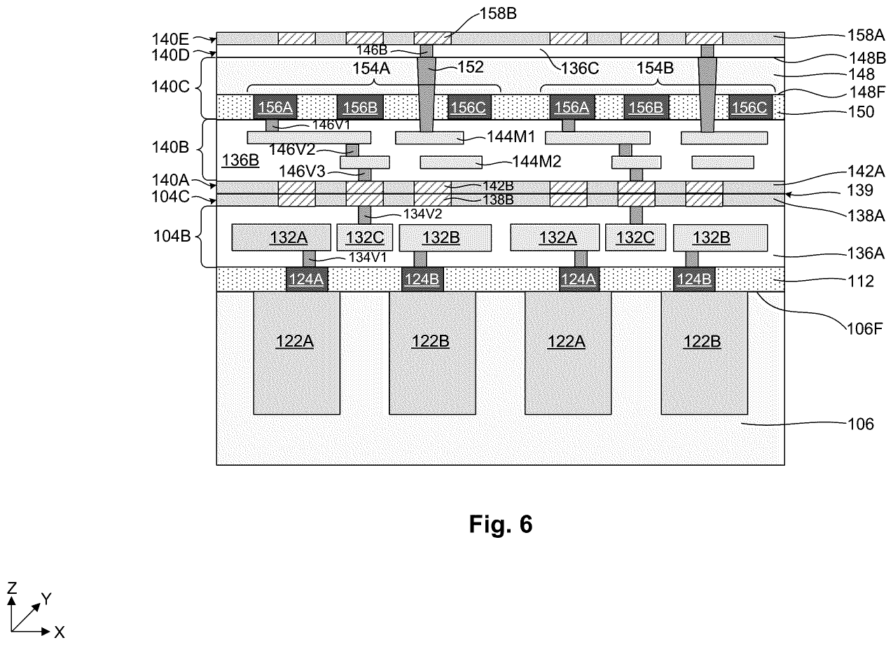

Referring to FIG. 2, in operation 220, TSVs, a third interconnect layer, and a third bonding layer of the second die layer are formed. For example, as described with reference to FIG. 6, TSVs 152, interconnect layer 140D, and bonding layer 140E of the second die layer are formed. In some embodiments, TSVs 152 can be formed extending vertically through substrate 148 and ILD layer 150, followed by the formation of conductive vias 146B on TSVs 152. The formation of conductive vias 146B can be followed by the formation of bonding layer 140E, which can include sequential operations of (i) depositing dielectric layer 158A on interconnect layer 140D and (ii) forming metal pads 158B in dielectric layer 158A.

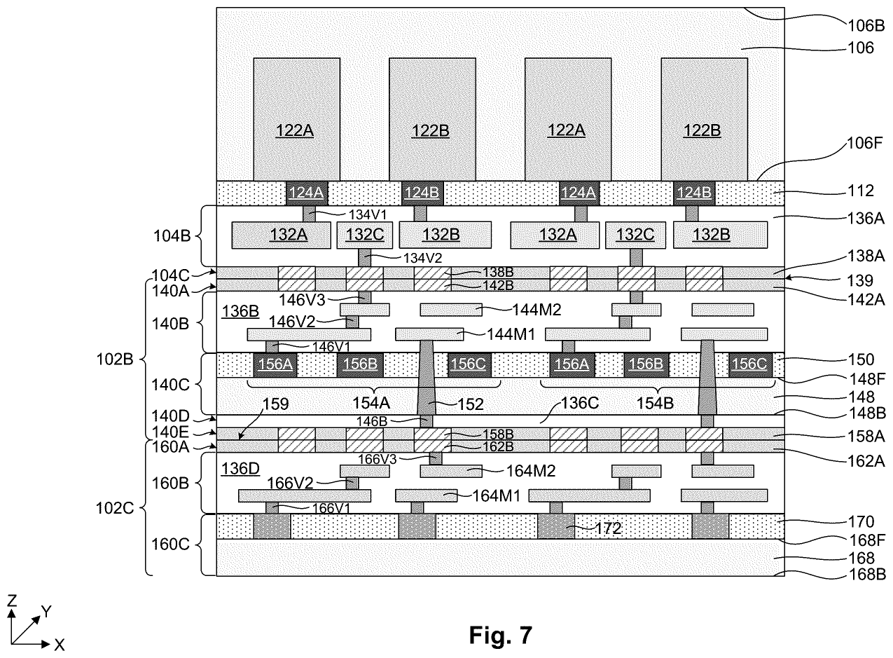

Referring to FIG. 2, in operation 225, a third die layer with devices, a fourth interconnect layer, and a fourth bonding layer is formed. For example, as described with reference to FIG. 7, third die layer 102C with devices 172, interconnect layer 160B, and bonding layer 160A is formed. In some embodiments, the formation of third die layer 102C can include sequential operations of (i) forming devices 172 on front-side surface 168F of substrate 168, (ii) depositing ILD layer 170 on front-side surface 178F of substrate 178, (iii) forming conductive vias 166V1 of interconnect layer 160B, (iv) forming metal lines 164M1 of interconnect layer 160B, (v) forming conductive vias 166V2 of interconnect layer 160B, (vi) forming metal lines 164M2 of interconnect layer 160B, (vii) forming conductive vias 166V3 of interconnect layer 160B, (viii) depositing dielectric layer 162A of bonding layer 160A on interconnect layer 160B, and (ix) forming metal pads 162B in dielectric layer 162A.

Referring to FIG. 2, in operation 230, a bonding process is performed between the second and third die layers. For example, as described with reference to FIG. 7, a bonding process is performed between die layers 102B and 102C. In some embodiments, performing the bonding process can include sequential operations of (i) performing an activation process with a plasma (e.g., hydrogen plasma) on top surfaces of bonding layers 140E and 160A, (ii) bringing metal pads 158B of bonding layer 140E in contact with corresponding metal pads 162B of bonding layer 160A, and (iii) performing an anneal process at a melting temperature of the material of metal pads 158B and 162B to form the structure of FIG. 7.

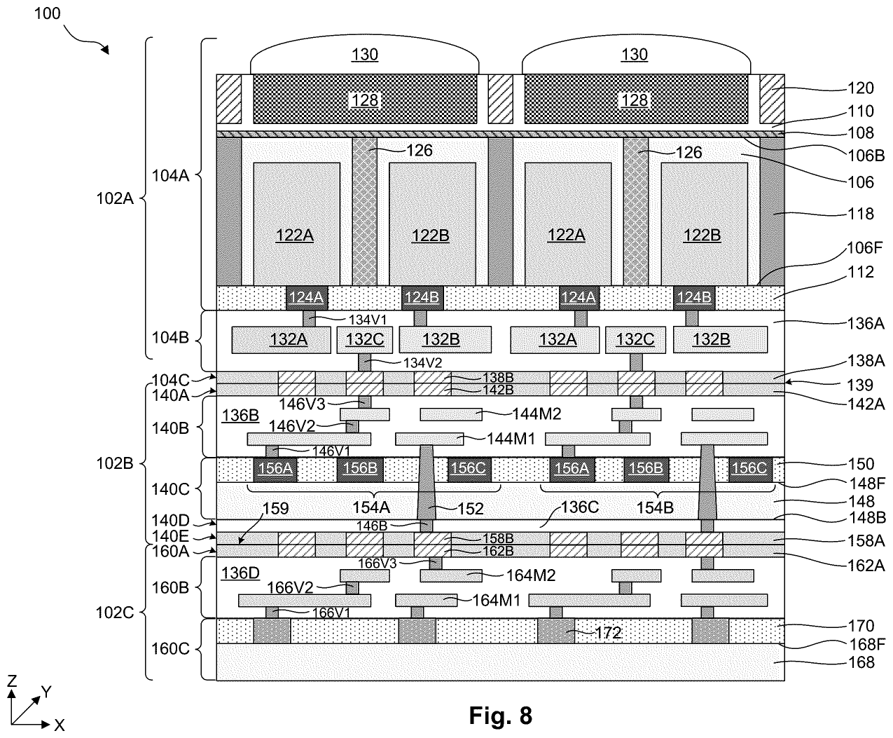

Referring to FIG. 2, in operation 235, isolation structures, color filters, grid structures, and micro-lenses of the first die layer are formed. For example, as described with reference to FIG. 8, inter-pixel isolation structures 118, intra-pixel isolation structures 126, color filters 128, metal grid structures 120, and micro-lenses 130 of first die layer 102A are formed. In some embodiments, inter-pixel isolation structures 118 and intra-pixel isolation structures 126 can be formed at the same time through back-side surface 106B of substrate 106. In some embodiments, the formation of inter-pixel isolation structures 118 and intra-pixel isolation structures 126 can include sequential operations of (i) performing a thinning process on back-side surface 106B of substrate 106, (ii) etching substrate 106 through back-side surface 106B to form trenches (not shown) in substrate 106, (iii) depositing a dielectric layer (not shown) in the trenches, and (iv) performing a chemical mechanical polishing (CMP) process on the deposited dielectric layer to form inter-pixel isolation structures 118 and intra-pixel isolation structures 126, as shown in FIG. 8.

The formation of inter-pixel isolation structures 118 and intra-pixel isolation structures 126 can be followed by the deposition of anti-reflective coating layer 108 on back-side surface 106B of substrate 106, which can be followed by the deposition of dielectric layer 110 on anti-reflective coating layer 108. Metal grid structures 120 and color filters 128 can be formed in dielectric layer 110, which can be followed by the formation of micro-lenses 130 on color filters 128.

The present disclosure provides example structures of a BSI image sensor (e.g., BSI image sensor 100) for improving sensor performance (e.g., increasing sensitivity to radiation, increasing full well capacity, reducing capacitance, and/or reducing cross-talk between adjacent pixel structures) and reducing manufacturing costs of the BSI image sensor. In some embodiments, the BSI image sensor can include dual radiation-sensing device (RSD)-based pixel structures (e.g., pixel structures 114A-114H), each of which can include first and second RSDs (e.g., RSDs 122A and 122B) and does not include more than two RSDs. Each of the first and second RSDs can have a rectangular-shaped radiation-sensing surface area (e.g., radiation-sensing areas 125). The rectangular-shaped radiation-sensing surface areas in each of the dual RSD-based pixel structures can provide a larger radiation-sensing surface area than a similar sized quadratic RSD-based pixel structure having four RSDs with square-shaped radiation-sensing surface areas. As a result, the dual RSD-based pixel structure can improve sensor performance (e.g., increased sensitivity to radiation and/or increased full well capacity) than quadratic RSD-based pixel structure.

In some embodiments, the BSI image sensor can further include inter-pixel isolation structures (e.g., inter-pixel isolation structures 118) surrounding each pixel structure to reduce electrical and optical cross-talk between adjacent pixel structures. Also, intra-pixel isolation structures (e.g., intra-pixel isolation structures 126) can be disposed between the first and second RSDs in each pixel structure to reduce electrical and optical cross-talk between the first and second RSDs of each pixel structure.

In some embodiments, each pair of adjacent pixel structures of the BSI image sensor can share a floating diffusion region (e.g., floating diffusion regions 116A and 116B) and a pixel transistor group (e.g., pixel transistor groups 154A and 154B) to reduce the manufacturing cost of the BSI image sensor compared to other BSI image sensors having an individual floating diffusion region and an individual pixel transistor group for each pixel structure. In addition, each floating diffusion region and each pair of adjacent pixel structures can be electrically coupled to a corresponding pixel transistor group through a single metal line layer (e.g., metal line layer Ml of interconnect layer 104B) in an interconnect layer. With the use of the single metal line layer, the manufacturing cost of the BSI image sensor can be further reduced compared to other BSI image sensors using multiple metal line layers for electrically coupling floating diffusion regions and pixel structures to corresponding pixel transistor groups.

In some embodiments, an optical device includes a first die layer and a second die layer. The first die layer includes a first substrate having a first surface and a second surface opposite to the first surface, first and second pixel structures, an inter-pixel isolation structure disposed in the first substrate, and a floating diffusion region disposed in the first substrate and between the first and second pixel structures. A first cross-section of the inter-pixel isolation structure along a first plane includes a rectangular-shaped enclosure around the first and second pixel structures, and a second cross-section of the inter-pixel isolation structure along a second plane includes a vertical structure separating the first and second pixel structures. The second die layer includes a second substrate having a third surface and a fourth surface opposite to the third surface and a pixel transistor group disposed on the third surface of the second substrate and electrically connected to the first and second pixel structures.

In some embodiments, an optical device includes a first die layer and a second die layer. The first die layer includes a first substrate having a first surface and a second surface opposite to the first surface, a first pixel structure having first and second radiation-sensing devices, a first floating diffusion region disposed in the first substrate and between the first and second radiation-sensing devices, a second pixel structure having third and fourth radiation-sensing devices, a second floating diffusion region disposed in the first substrate and between the third and fourth radiation-sensing devices, and an interconnect layer having a first metal line disposed on the second surface of the first substrate. The first metal line is electrically connected to the first and second floating diffusion regions. The second die layer includes a second substrate having a third surface and a fourth surface opposite to the third surface and a pixel transistor group disposed on the substrate and electrically connected to the first metal line.

In some embodiments, a method includes forming a first die layer with radiation-sensing devices in a first substrate, a first interconnect layer on the radiation-sensing devices, and a first bonding layer on the first interconnect layer. Each of the radiation-sensing devices includes a rectangular-shaped cross-sectional profile along a horizontal plane. The method further includes forming a second die layer with pixel transistors on a second substrate, a second interconnect layer on the pixel transistors, and a second bonding layer on the second interconnect layer, performing a bonding process between the first and second die layers, and forming an isolation structure surrounding the radiation-sensing devices.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An optical device, comprising:
a first die layer, comprising:
a first substrate comprising a first surface and a second surface opposite to the first surface;
first and second pixel structures;
an inter-pixel isolation structure disposed in the first substrate, wherein:
a first cross-section of the inter-pixel isolation structure along a first plane comprises a rectangular-shaped enclosure around the first and second pixel structures, and
a second cross-section of the inter-pixel isolation structure along a second plane comprises a vertical structure separating the first and second pixel structures; and
a floating diffusion region disposed in the first substrate and between the first and second pixel structures; and
a second die layer, comprising:
a second substrate comprising a third surface and a fourth surface opposite to the third surface; and
a pixel transistor group disposed on the third surface of the second substrate and electrically connected to the first and second pixel structures.

2. The optical device of claim 1, wherein the first pixel structure comprises:
first and second radiation-sensing devices in the first substrate; and
an intra-pixel isolation structure disposed in the first substrate and between the first and second radiation-sensing devices.

3. The optical device of claim 2, wherein the intra-pixel isolation structure extends vertically from the first surface of the first substrate to the second surface of the first substrate.

4. The optical device of claim 2, wherein a height of the intra-pixel isolation structure is greater than a height of the first radiation-sensing device.

5. The optical device of claim 1, wherein the first pixel structure comprises first and second radiation-sensing devices in the first substrate; and
wherein each of the first and second radiation-sensing devices comprise a rectangular-shaped cross-sectional profile along a horizontal plane.

6. The optical device of claim 1, wherein the first and second pixel structures comprise transfer gate structures electrically connected to a transistor in the pixel transistor group.

7. The optical device of claim 1, wherein the floating diffusion region is electrically connected to a transistor in the pixel transistor group.

8. The optical device of claim 1, wherein the floating diffusion region is configured to store charges transferred from the first and second pixel structures.

9. The optical device of claim 1, wherein the inter-pixel isolation structure extends vertically from the first surface of the first substrate to the second surface of the first substrate.

10. The optical device of claim 1, further comprising:
a first bonding layer disposed on the second surface of the first substrate;
a second bonding layer disposed on the third surface of the second substrate; and
a third bonding layer disposed on the fourth surface of the second substrate.

11. An optical device, comprising:
a first die layer, comprising:
a first substrate comprising a first surface and a second surface opposite to the first surface;
a first pixel structure comprising first and second radiation-sensing devices;
a first floating diffusion region disposed in the first substrate and between the first and second radiation-sensing devices;
a second pixel structure comprising third and fourth radiation-sensing devices;
a second floating diffusion region disposed in the first substrate and between the third and fourth radiation-sensing devices; and
an interconnect layer comprising a first metal line disposed on the second surface of the first substrate, wherein the first metal line is electrically connected to the first and second floating diffusion regions; and
a second die layer, comprising:
a second substrate comprising a third surface and a fourth surface opposite to the third surface; and
a pixel transistor group disposed on the substrate and electrically connected to the first metal line.

12. The optical device of claim 11, further comprising an isolation structure disposed in the first substrate, wherein a top surface of the isolation structure is substantially coplanar with the first surface of the first substrate and a bottom surface of the isolation structure is substantially coplanar with the second surface of the first substrate.

13. The optical device of claim 11, wherein each of the first and second radiation-sensing devices comprise a rectangular-shaped cross-sectional profile along a horizontal plane.

14. The optical device of claim 11, wherein the pixel transistor group comprises a source follower transistor, a reset transistor, and a row selector transistor.

15. The optical device of claim 11, wherein the interconnect layer further comprises second and third metal lines; and
wherein the second metal line is electrically connected to the first pixel structure and the third metal line is electrically connected to the second pixel structure.

16. The optical device of claim 15, wherein the second and third metal lines are electrically connected to an other pixel transistor in the second die layer.

17. A method, comprising:
forming a first die layer with radiation-sensing devices in a first substrate, a first interconnect layer on the radiation-sensing devices, and a first bonding layer on the first interconnect layer, wherein each of the radiation-sensing devices comprise a rectangular-shaped cross-sectional profile along a horizontal plane;
forming a second die layer with pixel transistors on a second substrate, a second interconnect layer on the pixel transistors, and a second bonding layer on the second interconnect layer;
performing a bonding process between the first and second die layers; and
forming an isolation structure surrounding the radiation-sensing devices.

18. The method of claim 17, wherein forming the isolation structure comprises forming the isolation structure with top and bottom surfaces substantially coplanar with first and second surfaces of the first substrate, respectively.

19. The method of claim 17, wherein forming the first die layer further comprises forming an other isolation structure in the first substrate and between the radiation-sensing devices.

20. The method of claim 17, wherein forming the first die layer further comprises forming a floating diffusion region between the radiation-sensing devices.
